(19) United States
(12) Patent Application Publication
(10) Pub. No.: US 2020/0144866 A1
(43) Pub. Date: May 7, 2020

(54) REMOTE POWER TRANSMISSION TO AN AIRSHIP

(71) Applicant: LOCKHEED MARTIN CORPORATION, Bethesda, MD (US)

(72) Inventors: Steven Lloyd SINSABAUGH, Abingdon, MD (US); Dennis John ADAMS, Akron, OH (US); Eric C. HONEA, Bothel, WA (US)

(21) Appl. No.: 16/178,387

(22) Filed: Nov. 1, 2018

(51) Int. Cl. H02J 50/30; B60L 9/00; H02S 40/38; H02S 40/22; H01L 35/02; H01L 37/02; H02J 50/40; B60L 8/00

(52) U.S. Cl. CPC H02J 50/30; B60L 9/00; H02S 40/38; H02S 40/22; B64B 1/02; H01L 37/02; H02J 50/40; B60L 8/003; H01L 35/02

(57) ABSTRACT

A ground-, sea- or aircraft-based laser transmission system can be implemented to remotely and wirelessly transmit power to an airship to be stored in an energy storage device, such as a battery. The airship can include an energy collection system having a plurality of photovoltaic cells arranged in an array and electrically coupled to the energy storage system. The energy collection system can also include one or more control link components positioned adjacent the array of photovoltaic cells. The control link components are configured to establish a control link between the airship and a power transmission system. The plurality of photovoltaic cells are configured to transfer laser beam transmitted energy from the power transmission system to the energy storage system.

### FIELD

The present disclosure relates, in general, to airships and, more particularly, to remote power transmission to an airship.

### BACKGROUND

The following description is provided to assist the understanding of the reader. None of the information provided or references cited is admitted to be prior art.

An airship provides a platform that contains a lifting gas, which provides lift and enables vehicle operations. Flight platforms such as airships can carry payloads that provide capabilities such as surveillance or communications over a geographic region. These platforms can be unmanned and are capable of extended flight of weeks to months to years, with the ability to fly back and be recovered and reused. These platforms have distinct advantages over existing systems, such as satellites or ground-based solutions. For instance, such platforms can maintain position over a particular area for extended periods, using various energy architectures, such as, but not limited to solar regenerative systems to capture solar energy during daytime and store excess energy in batteries, capacitors or other energy storage mediums for use at night for propulsion and payload power. With this power such airships can overcome the normally benign winds to effectively hold a specific position.

### SUMMARY

Methods and systems are described for, among other things, an energy collection device for an airship and a power transmission system for remotely and wirelessly transmitting power to the energy collection device via one or more laser beams.

According to some implementations, a system can include an airship that has an outer casing with an exterior surface and containing a gas therein. The airship can include an energy storage system having one or more energy storage devices, an energy distribution and control system electrically coupled to the energy storage system and configured to distribute power from the energy storage system to one or more systems of the airship, and an energy collection system coupled to the exterior surface of the outer casing. The energy collection system can include a laser tolerant layer, an insulation layer, a plurality of photovoltaic cells arranged in an array and electrically coupled to the energy storage system, and one or more retroreflectors positioned adjacent the array of photovoltaic cells. The system can also include a power transmission system. The power transmission system can include plurality of power transmission lasers, a beam control system for the plurality of power transmission lasers, one or more control link lasers, and a controller. The controller can be configured to establish a control link between the power transmission system via the one or more control link lasers and the retroreflectors of the airship and control the plurality of power transmission lasers to transmit power to the airship. The laser beams of the plurality of power transmission lasers can overlap to achieve a substantially uniform irradiance level and power distribution spatial profile at the plurality of photovoltaic cells of the airship.

According to some implementations, an airship can include an outer casing, an energy storage system having one or more energy storage devices, an energy distribution and control system electrically coupled to the energy storage system and configured to distribute power from the energy storage system to one or more systems of the airship, and an energy collection system positioned outside the outer casing. The energy collection system can include a plurality of photovoltaic cells arranged in an array and electrically coupled to the energy storage system and one or more control link components positioned adjacent the array of photovoltaic cells. The one or more control link components can be configured to establish a control link between the airship and a power transmission system. The plurality of photovoltaic cells can be configured to transfer laser beam transmitted energy from the power transmission system to the energy storage system.

According to some implementations, a power transmission system can include plurality of power transmission lasers, a beam control system for the plurality of power transmission lasers, one or more control link lasers, and a controller. The controller can be configured to establish a control link between the power transmission system and an airship via the one or more control link lasers and one or more control link components of the airship and control the plurality of power transmission lasers to transmit power to the airship. The laser beams of the plurality of power transmission lasers can overlap to achieve a substantially uniform irradiance level and power distribution spatial profile at a plurality of photovoltaic cells of the airship.

According to some implementations, an energy collection system can include a plurality of photovoltaic cells arranged in an array and electrically coupled to an energy storage system and one or more control link components positioned adjacent the array of photovoltaic cells. The one or more control link components can be configured to establish a control link with a power transmission system. The plurality of photovoltaic cells can be configured to transfer laser beam transmitted energy from the power transmission system to the energy storage system.

According to some implementations, an energy collection system can include a plurality of thermo-electrical cells arranged in an array and electrically coupled to an energy storage system and one or more control link components positioned adjacent the array of thermo-electrical cells. The one or more control link components can be configured to establish a control link with a power transmission system. The plurality of thermo-electrical cells can be configured to transfer laser beam transmitted energy from the power transmission system to the energy storage system.

According to some implementations, an energy collection system can include a plurality of photothermal cells arranged in an array and electrically coupled to an energy storage system and one or more control link components positioned adjacent the array of photothermal cells. The one or more control link components can be configured to establish a control link with a power transmission system. The plurality of photothermal cells can be configured to transfer laser beam transmitted energy from the power transmission system to the energy storage system.

According to some implementations, an energy collection system can include a plurality of pyroelectrical cells arranged in an array and electrically coupled to an energy storage system and one or more control link components positioned adjacent the array of pyroelectrical cells. The one or more control link components can be configured to establish a control link with a power transmission system. The plurality of pyroelectrical cells can be configured to transfer laser beam transmitted energy from the power transmission system to the energy storage system.

According to some implementations, an energy collection system can include a plurality of optical rectennas arranged in an array and electrically coupled to an energy storage system and one or more control link components positioned adjacent the array of optical rectennas. The one or more control link components can be configured to establish a control link with a power transmission system. The plurality of optical rectennas can be configured to transfer laser beam transmitted energy from the power transmission system to the energy storage system.

According to some implementations, an energy collection system can include means for establishing a control link with a power transmission system and means for converting and transferring laser beam transmitted energy from the power transmission system to an energy storage system.

According to some implementations, a power transmission system can include means for establishing a control link with an energy collection system of an airship and means for transmitting power to the airship responsive to establishing the control link.

The foregoing summary is illustrative only and is not intended to be in any way limiting. In addition to the illustrative aspects, embodiments, and features described above, further aspects, embodiments, and features will become apparent by reference to the following drawings and the detailed description.

### BRIEF DESCRIPTION OF THE DRAWINGS

The details of one or more implementations are set forth in the accompanying drawings and the description below. Other features, aspects, and advantages will become apparent from the description, the drawings, and the claims, in which:

FIG. 1 is an overview of some airships;

FIG. 2 is an illustrative diagram of the airships of FIG. 1 showing components thereof;

FIG. 3 is an overview of some air-based power transmission systems;

FIG. 4A is an overview of some land-based power transmission systems;

FIG. 4B is an overview of some sea-based power transmission systems;

FIG. 5 is a front view of the airships of FIG. 2 showing some embodiments of an energy collection system receiving laser energy;

FIG. 6 is a partial cross-sectional view of an energy collection system and an exterior of the airship during power transmission;

FIG. 7 is an illustrative diagram depicting some energy collection systems and showing control link regions of the energy collection array;

FIG. 8 is a block diagram of some remote power transmission systems;

FIG. 9 is a top view depicting some laser transmission arrays for remote power transmission;

FIG. 10 is a process diagram depicting some processes for remote power transmission; and

FIG. 11 is a block diagram illustrating a general architecture for some computer systems that may be employed to implement various elements of the systems and methods described and illustrated herein.

It will be recognized that some or all of the figures are schematic representations for purposes of illustration. The figures are provided for the purpose of illustrating embodiments with the explicit understanding that they will not be used to limit the scope or the meaning of the claims.

### DETAILED DESCRIPTION

Stratospheric flight platforms, such as airships, provide capabilities such as surveillance or communications over a large geographic region. These platforms can be unmanned and are capable of extended flight of weeks to months to years, with the ability to fly back and be recovered and reused. These platforms have advantages over existing systems, such as satellites or ground-based solutions as such platforms can maintain position over a particular area for extended periods, using various energy architectures, such as but not limited to solar regenerative systems, to capture solar energy during daytime and store excess for use at night for propulsion and payload power. With this power such airships can overcome the normally benign winds at high altitudes to effectively hold a specific position. However, there are limitations on energy storage and/or acquisition under certain conditions, such as high latitudes, short daytime hours with long nights during winter seasons, and occasional high wind events. Under such conditions the volume and mass constraints of a stratospheric platform can limit the amount of energy that can be gathered and stored. Thus, provided herein are systems and methods to remotely power the platform using an energy transmission system, such as a laser transmission system.

Such a system can include a ground-, sea-, or aircraft-based laser transmission system, an airship-based collection system, and a control and feedback system that aligns the lasers to focus on the airship-based collection system and can provide beam control and optimization functions. Such power transmission systems can provide power for an airship that has a malfunctioning and/or otherwise reduced output power system to maneuver to a destination. In other instances, such a system can be used to assist in launching or otherwise initially positioning the airship. In further instances, such a system can be used to provide supplemental power to the airship to overcome high wind periods, or to execute other high energy maneuvers.

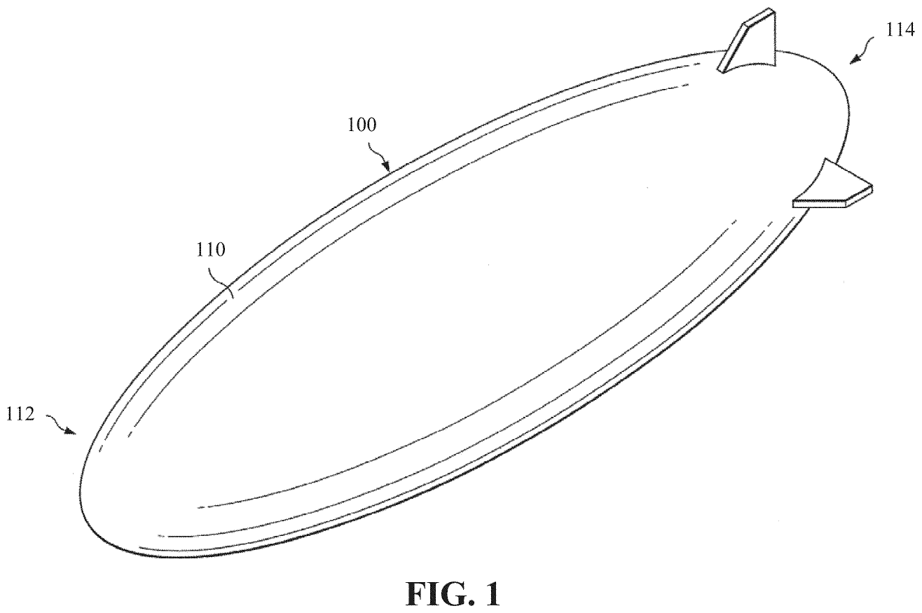

FIG. 1 depicts an example of an airship 100 having a gas-filled membrane 110. The gas-filled membrane 110 is in the shape of an airship hull and has a first end 112 and a second end 114. The airship hull may have any suitable dimensions. The gas-filled membrane 110 may be made from any suitable material, such as, for example, a high-performance film capable of creating a suitable gas barrier and providing protection from the environment. In some cases, the gas-filled membrane 110 may be formed from a single kind of material or from a plurality of different materials. In certain implementations, the gas-filled membrane 110 may be formed from MYLAR or other high performance films. The gas-filled membrane 110 may be treated with one or more resins, for example with a urethane resin. In some implementations, the gas-filled membrane 110 may include several sub-structures of gas-filled membranes such that the gas-filled membrane 110 provides an outer membrane or an outer casing to contain the sub-structures.

The gas-filled membrane 110 may be formed from a film capable of creating a suitable gas barrier, which can be used for airships and aerostats to retain the gasses with which they are filled. In some cases, the material from which the gas-filled membrane 110 is formed may vary depending on the type of gas intended to be used with the gas-filled membrane 110. The gas-filled membrane 110 may be filled with any suitable gas, such helium, hydrogen, or other gases.

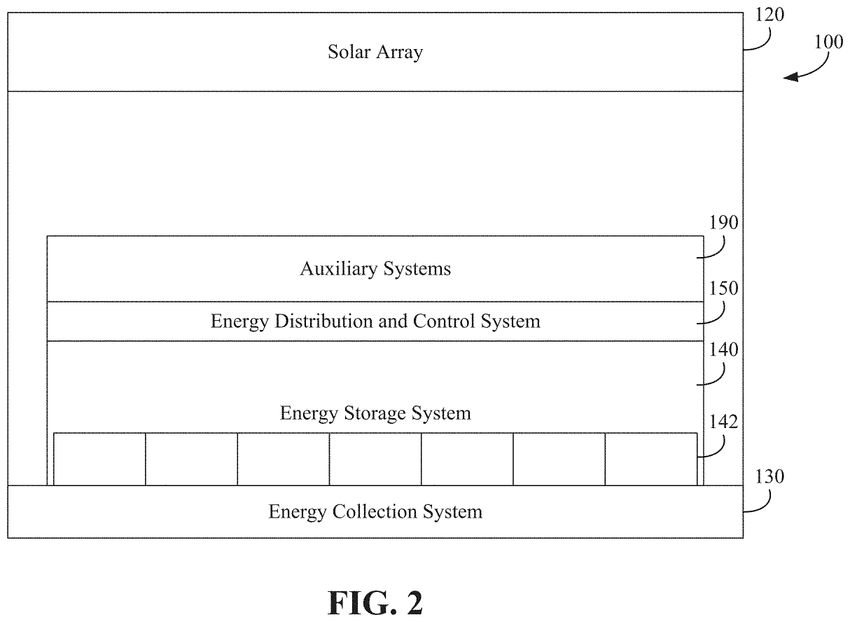

FIG. 2 depicts an overview of the airship 100 of FIG. 1 with components thereof. The airship 100 can include a solar array 120 positioned on an exterior surface of the gas-filled membrane 110 and/or on an exterior structure (e.g., a tail fin, an exterior mount, and/or other structure). The solar array 120 can include one or more photovoltaic cells, such as an amorphous silicon (a-Si) photovoltaic cells. The photovoltaic cells can be arranged in an array and mounted to the exterior surface of the gas-filled membrane 110 and/or on an exterior structure (e.g., a tail fin, an exterior mount, and/or other structure).

The solar array 120 is electrically coupled to an energy storage system 140 to transmit energy produced from the photovoltaic cells to one or more energy storage devices 142. The one or more energy storage devices 142 can include batteries, capacitors, etc. In some implementations, the energy storage devices 142 include lithium-ion cells formed into battery modules. The energy storage system 140 is electrically coupled to an energy distribution and control system 150. The energy distribution and control system 150 can include a power distribution unit, an array control unit, a controller, and/or any other components utilized for power distribution from the energy storage system 140 and/or to control components of the power subsystem of the airship 100, such as the solar array 120. In some implementations, the power distribution unit can provide power management and control of electrical loads to components of the power subsystem and/or other systems of the airship 100 (e.g., power to actuators for control surfaces, propulsion systems, etc.). An array control unit can monitor photovoltaic performance of the solar array 120 and/or individual photovoltaic components and can monitor, control, and route energy transmitted by the solar array 120 or components thereof. The airship 100 can further include one or more auxiliary systems 190, such as surveillance systems, sensor systems, communications systems, etc.

As noted above, in situations where the energy produced from the solar array 120 is reduced (e.g., winter reduced daylight hours, high latitude or polar regions, etc.) or provides insufficient power (e.g., high wind conditions, high power consumption auxiliary systems, etc.), the airship 100 can include a separate energy collection system 130. The energy collection system 130 is also electrically coupled to the energy storage system 140 for transmitting energy received from a remote power transmission system to the one or more energy storage devices 142. In the implementations described herein, a laser-based energy collection system 130 is described. The energy collection system 130 can include one or more photovoltaic cells configured to receive transmitted energy from a remote power transmission system as will be described in greater detail herein. In some implementations, an array of photovoltaic cells can be arranged on an exterior surface of the gas-filled membrane 110 and/or on an exterior structure (e.g., a tail fin, an exterior mount, and/or other structure).

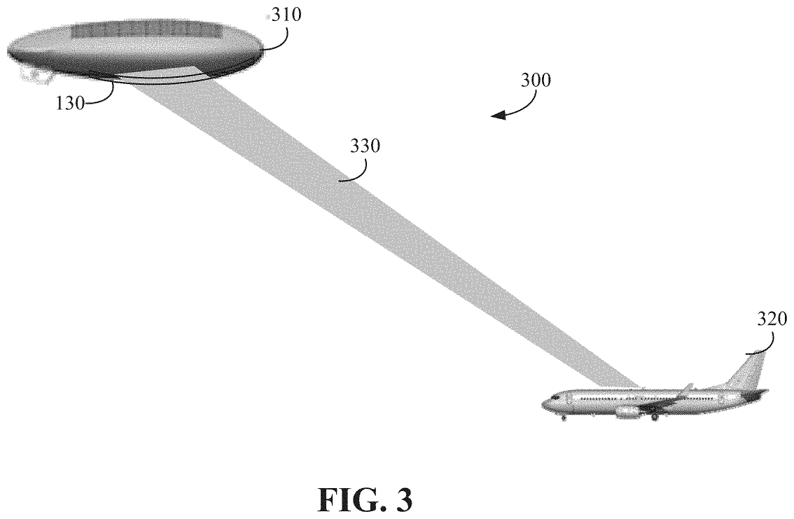

FIG. 3 depicts an overview of an air-based remote power transmission system 300 depicting an airship 310 having the energy collection system 130 and an aircraft or other vehicle 320 transmitting power to the energy collection system 130 of the airship 310. As shown, the aircraft 320 can direct a laser beam 330 to transmit power to the energy collection system 130 of the airship 310. The aircraft 320 can adjust the direction of the laser beam 330 while the aircraft 320 is moving such that power can be transmitted as the aircraft 320 flies under the airship 310 and/or circles below the airship 310. A control link, as will be described in greater detail herein, or other control transmission can be established between the aircraft 320 and the airship 310 to provide communication and/or positional information of the airship 310 and/or the energy collection system 130. The power transmission system can utilize such information to modify a directional vector of the laser beam 330 to transmit power to the energy collection system 130.

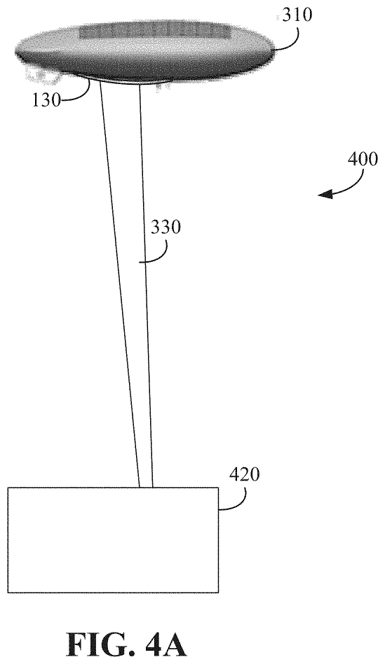

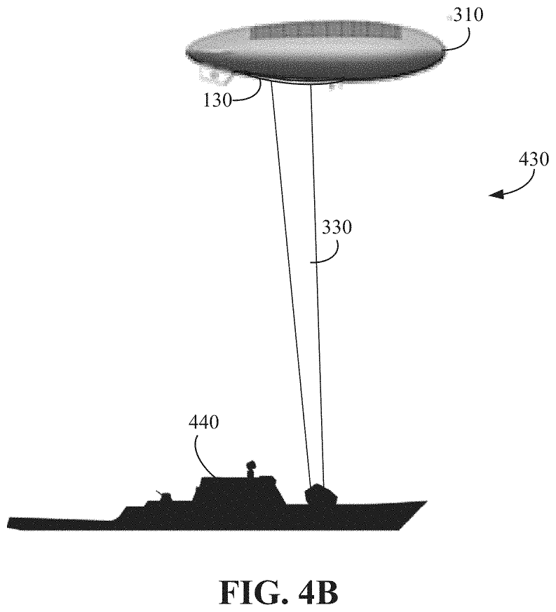

FIG. 4A depicts an overview of a ground-based remote power transmission system 400 depicting the airship 310 having the energy collection system 130 and a ground-based power transmission system 420 transmitting power to the energy collection system 130 of the airship 310. In some implementations, the ground-based power transmission system 420 can be fixed, such as a power transmission system mounted to a building or a standalone fixed power transmission system. In other implementations, the ground-based power transmission system 420 can be mobile, such as a ground vehicle power transmission system that can be repositioned. As shown, the ground-based power transmission system 420 can direct the laser beam 330 to transmit power to the energy collection system 130 of the airship 310. The ground-based power transmission system 420 can adjust the direction of the laser beam 330 if the airship 310 is moving. A control link, as will be described in greater detail herein, or other control transmission can be established between the ground-based power transmission system 420 and the airship 310 to provide communication and/or positional information of the airship 310 and/or the energy collection system 130. The power transmission system can utilize such information to modify a directional vector of the laser beam 330 to transmit power to the energy collection system 130.

FIG. 4B depicts an overview of a sea-based remote power transmission system 430 depicting the airship 310 having the energy collection system 130 and a sea-based power transmission system 440 transmitting power to the energy collection system 130 of the airship 310. The sea-based remote power transmission system 430 may be particularly useful when the airship 310 is near a metropolitan area where it is not practical to utilize a ground-based system, or when the airship 310 is near an archipelago (e.g., Japan, Indonesia, Singapore) where land is at a premium. In some implementations, the sea-based power transmission system 440 can be mobile, such as a boat, barge, or ship power transmission system that can be repositioned. In other implementations, the sea-based power transmission system 440 can be fixed, such as a power transmission system mounted to a dock, oil platform, or anchored buoy. As shown, the sea-based power transmission system 440 can direct the laser beam 330 to transmit power to the energy collection system 130 of the airship 310. The sea-based power transmission system 440 can adjust the direction of the laser beam 330 if the airship 310 is moving. A control link, as will be described in greater detail herein, or other control transmission can be established between the sea-based power transmission system 440 and the airship 310 to provide communication and/or positional information of the airship 310 and/or the energy collection system 130. The power transmission system can utilize such information to modify a directional vector of the laser beam 330 to transmit power to the energy collection system 130.

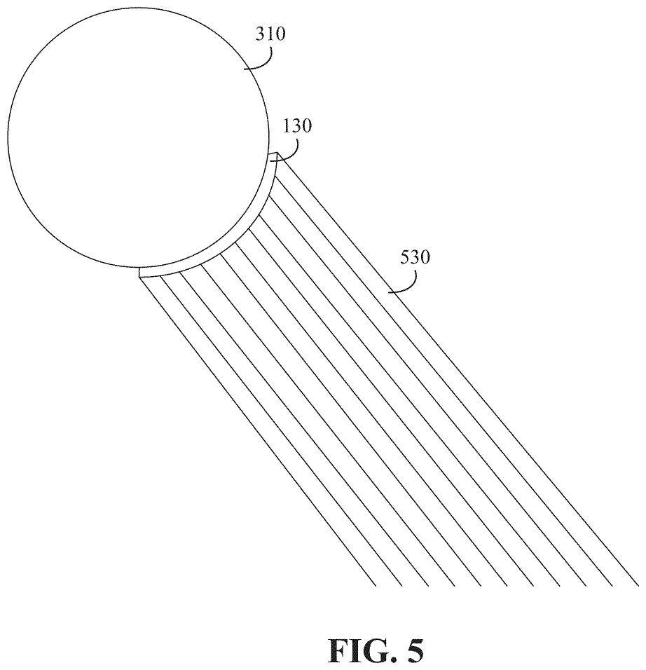

FIG. 5 depicts a front elevation view of the airship 310 having the energy collection system 130 and showing power being transmitted through a plurality of laser beams 530. The plurality of laser beams 530 can be used as the laser light impinging on different areas of the energy collection system 130 can be affected by the cosine angle between the laser axis and the plane of the corresponding photovoltaic cell receiving the laser beam transmission. By providing a plurality of laser beams 530, each of the plurality of laser beams 530 can be individually controlled such that laser light intensity, power, and/or directionality on different areas of the energy collection system 130 can compensate for the different impingement in order to maximize efficiency of the energy collection system 130.

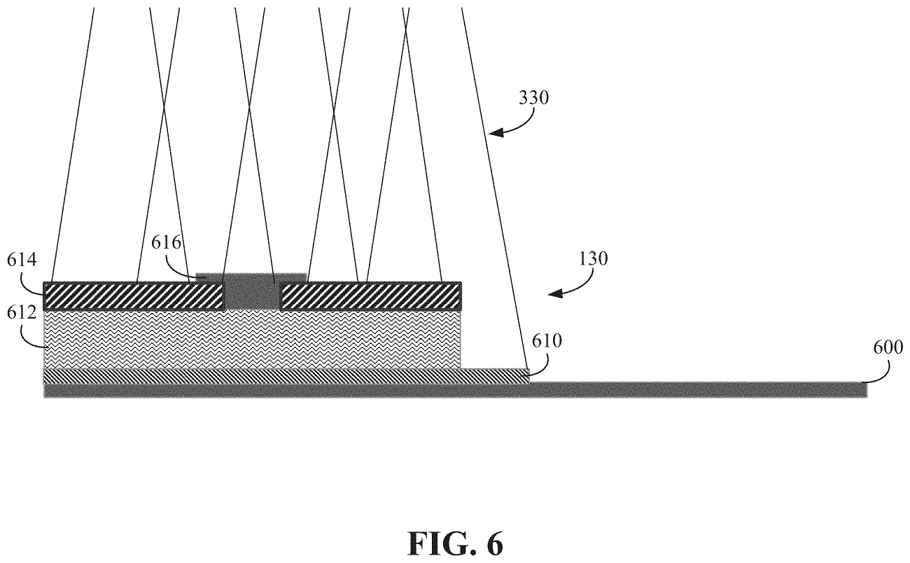

FIG. 6 depicts a partial cross-sectional view of the energy collection system 130 mounted on an exterior surface 600 of the outer casing of the airship. In some implementations, the exterior surface 600 can include reinforcement at the location where the energy collection system 130 is mounted. Such reinforcement may include additional fabric and/or coatings. In some implementations, a material for the reinforcement may be selected to tolerate intermittent laser irradiance and increased thermal loads. In some implementations, the energy collection system 130 can be mounted to a separate frame or mounting structure that is offset from the exterior surface 600. Such a structure can provide thermal insulation and/or cooling via the resulting air gap.

In the implementation shown, the energy collection system 130 includes a laser tolerant layer 610, an insulation layer 612, one or more photovoltaic cells 614, and one or more interconnects 616 electrically coupling the one or more photovoltaic cells 614. The laser tolerant layer 610 is a layer of material capable of continuous irradiance by a laser beam 330 that results from spillover from the laser beams 330. The laser tolerant layer 610 can be made of polyimide. In some implementations, the laser tolerant layer 610 can be integrated into the exterior surface 600 of the airship or can be omitted entirely. In some implementations, the laser tolerant layer 610 is capable of continuous irradiation from a laser energy of above 500 W/m², above 1000 W/m², such as 1355 W/m² (i.e., a typical solar radiation level), or above 1500 W/m² to protect the underlying exterior surface 600 of the airship. In some implementations, the laser tolerant layer 610 is capable of continuous irradiation from a laser energy of above 10,000 W/m². For example, a 500 kW received laser power impinging on a 50 m² collection array would have an average irradiance of 10,000 W/m².

An insulation layer 612 is provided between the one or more photovoltaic cells 614 and the laser tolerant layer 610. The insulation layer 612 is a layer of material capable of thermal and/or irradiance insulation to limit heat transfer and/or irradiance resulting from the laser beams 330 directed at the one or more photovoltaic cells 614. The insulation later 612 can be made of expanded polyimide foams. In some implementations, the insulation later 612 can be integrated into the exterior surface 600 of the airship or can be omitted entirely.

The one or more photovoltaic cells 614 are shown coupled to the exterior surface 600 of the airship via the insulation layer 612 and the laser tolerant layer 610. In implementations where two or more photovoltaic cells 614 are provided, an interconnect 616 can electrically couple a photovoltaic cell 614 to another photovoltaic cell 614. The interconnect 616 provides for high current electrical coupling between photovoltaic cells 614. The one or more photovoltaic cells 614 can be arranged in series, in parallel, or in both series and parallel. The one or more photovoltaic cells 614 convert the transmitted laser beam 330 energy to DC electrical power that is used and/or stored in one or more energy storage devices, such as energy storage devices 142 of FIG. 2. The one or more photovoltaic cells 614 can be optical wavelength photovoltaic cells or infrared (IR) photovoltaic cells. The bandgap for the one or more photovoltaic cells 614 can be selected and/or optimized for the wavelength of the laser beam. While one or more photovoltaic cells 614 are shown, other components capable of converting laser energy to electrical power can be utilized, either in lieu of the photovoltaic cells 614 or in addition to the photovoltaic cells 614. For example, optical rectennas, thermo-electrical components, photothermal components, pyroelectrical components, and/or combinations thereof can be used in lieu of the photovoltaic cells 614 or in addition to the photovoltaic cells 614.

As shown in FIG. 6, several laser beams 330 are arranged in an overlapping manner to provide a consistent distribution of irradiance to the one or more photovoltaic cells 614. That is, a power transmission system, as will be described in greater detail herein, can utilize an array of laser systems to effectuate the remote power transmission to the energy collection system 130. As noted in reference to FIG. 5, several laser beams 330 can be used as the laser light impinging on different areas of the energy collection system 130 can be affected by the cosine angle between the laser axis and the plane of the corresponding photovoltaic cell 614 receiving the laser beam 330 transmission. By providing several laser beams 330, each of the laser beams 330 can be individually controlled such that laser light intensity, power, and/or directionality on different areas of the energy collection system 130 can compensate for the different impingement in order to maximize efficiency of the energy collection system 130. That is, each of the laser beams 330 can be adjusted to maximize the energy transferred to each of the one or more photovoltaic cells 614.

In some implementations, a lens, filter, or other optical device can be positioned above one or more of the one or more photovoltaic cells 614 such that the path and/or content of the laser beam can be modified. For instance, a Fresnel lens can be implemented to redirect received laser beam light to a perpendicular path to the one or more photovoltaic cells 614.

In some implementations, temperature control devices, such as thermal monitors, insulation, heaters, etc., can be implemented with the energy collection system 130 to adjust and/or maintain operating characteristics of the optical-to-electrical conversion devices, such as photovoltaic cells 614, optical rectennas, thermo-electrical components, photothermal components, pyroelectrical components, and/or combinations thereof.

In some implementations, the energy collection system 130 and/or the airship can include optical sensors and/or thermal sensors to measure a spatial distribution of received laser beams 330 on the energy collection system 130 and/or adjacent portions of exterior surface 600 of the airship.

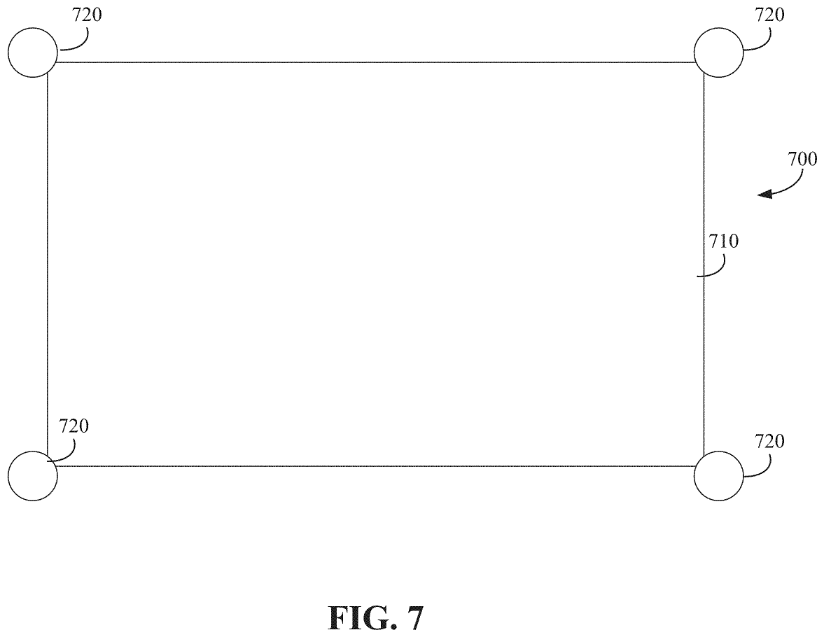

FIG. 7 depicts an implementation of an energy collection system 700 that includes an array 710 of energy collection elements, such as the photovoltaic cells 614 of FIG. 6, optical rectennas, thermo-electrical components, photothermal components, pyroelectrical components, and/or combinations thereof. The array 710 can be positioned on an insulation layer and/or a laser tolerant layer on the exterior surface of the airship or the array 710 can be directly mounted to the exterior surface of the airship. The energy collection system 700 includes two or more control link components 720. The control link components 720 can be retroreflectors, modulated retroreflectors, IR receivers or transceivers, radio frequency (RF) receivers or transceivers, and/or any other component through which a position of the airship, laser beam(s), and/or the energy collection system 700 can be ascertained. The control link components 720 optically transmit control link information back to a power transmission system to provide for alignment of one or more laser beams directed to the array 710 to achieve a desired irradiance level and/or irradiated spatial profile at the array 710 of the airship.

In implementations with retroreflectors, one or more control laser beams can be used to detect the retroreflector via the reflection of the control laser beam(s) back to the power transmission system. The control laser beams can be mechanically or optically co-aligned with the transmitted power transfer laser beam(s). Such retroreflectors passively provide the area of the array 710 for the power transmission system such that the power transmission system can adjust and/or maintain the direction of the irradiation from the laser beams for the photovoltaics of the array 710. In some implementations, the position of the retroreflector, the number of retroreflectors, the shape of the retroreflector, and/or the composition of the reflected control laser beam can be used to determine information about the airship and/or the energy collection system 700, such as the shape of the array 710, the size of the array 710, the curvature of the array 710, etc.

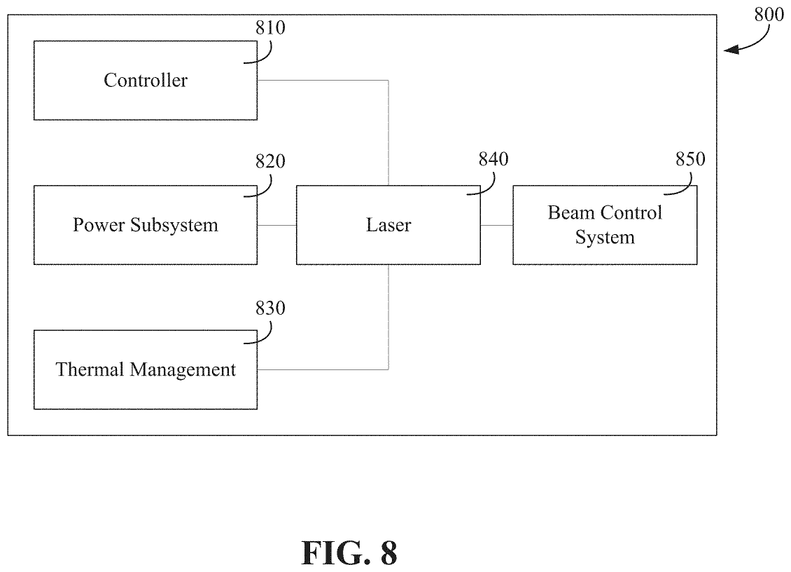

FIG. 8 depicts an implementation of a power transmission system 800 having a controller 810, a power subsystem 820, a thermal management system 830, a laser 840, and a beam control system 850. The power subsystem 820 modifies and/or transfers the primary power for the laser 840 to generate the laser beam for power transmission. The thermal management system 830 can monitor and control the thermal loads generated during operation of the power transmission system. The laser 840 can be a fiber laser, a laser diode, an IR laser (such as a CO₂ laser), a low irradiance laser, a solid state laser, or other laser system. In some implementations, the laser 840 can be a 3-kW fiber laser transmitting a 5 cm Gaussian beam through a 10 cm subaperture. In some implementations, the laser 840 can have a wavelength of between 400 nm and 1200 nm, such as 1060 nm. In some implementations, the wavelength of the laser 840 is optimized by the controller 810 (e.g., a fiber laser may be tuned between a wavelength of 1020 nm and 1100 nm) based on atmospheric transmission considerations and a spectral response of the energy collection elements (e.g., photovoltaic cells, optical rectennas, thermo-electrical components, photothermal components, pyroelectrical components). The beam control system 850 can include one or more lenses, reflectors, and/or other optical components to shape and control the direction of the emitted laser beam from the laser 840.

The controller 810 is communicatively coupled to the laser 840 and/or beam control system 850 to control operation thereof. The controller 810 is configured to adjust the intensity of power transmission of the laser 840 and/or the orientation of the laser 840, either directly or through the beam control system 850, to achieve a desired irradiance level and/or a spatial profile at an energy collection system of an airship. In some implementations, the controller 810 can control several lasers 840 and/or beam control system 850 to superimpose and/or offset the angle of the one or more lasers 840 to achieve a desired irradiance level and/or power distribution spatial profile at the energy collection system of the airship.

In some implementations, the controller 810 can be configured to modify operation of the laser 840 responsive to control link component feedback from an airship. For instance, for retroreflector control link components, the controller 810 may be configured to pause or turn off the laser 840 responsive to an interruption of the control link. For instance, if an object enters between the power transmission system and the airship that blocks the control link laser, the controller 810 can pause or turn off the laser 840 and/or operate the beam control system 850 to block the laser beam transmission. In some implementations, the controller 810 is configured to adjust the power output and/or spatial profile such that irradiated power outside the array and/or beyond the array on the airship is low or non-existent to minimize potential damage to other equipment and/or entities.

In some implementations, the power transmission system 800 includes control link lasers and control link beam control systems in addition to the power transmission lasers 840. The controller 810 can also control the control link lasers that are directed towards the control link component of the airship. In some implementations, the power transmission system 800 further includes control link receivers configured to monitor the transmitted and/or retro-reflected control signals from the airship.

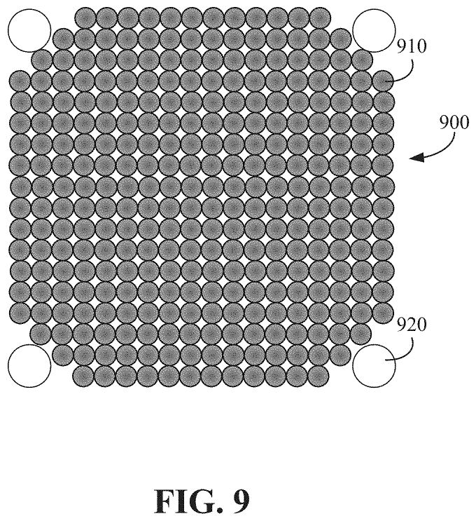

FIG. 9 depicts an array 900 of power transmission laser beams 910 in a substantially square spatial profile. One or more control link laser beams 920 can be provided at a predetermined position relative to the array 900. In some implementations, the array 900 can include 300 3-kW incoherently-combined fiber lasers, each transmitting a 5 cm Gaussian beam through a 10 cm subaperture such that the total optical output of the array is 900 kW. One or more beam control systems of a power transmission system can adjust the orientation of one or more of the power transmission laser beams 910 to form an array of overlapping beams having a desired irradiance level and/or power distribution spatial profile at an energy collection system of an airship.

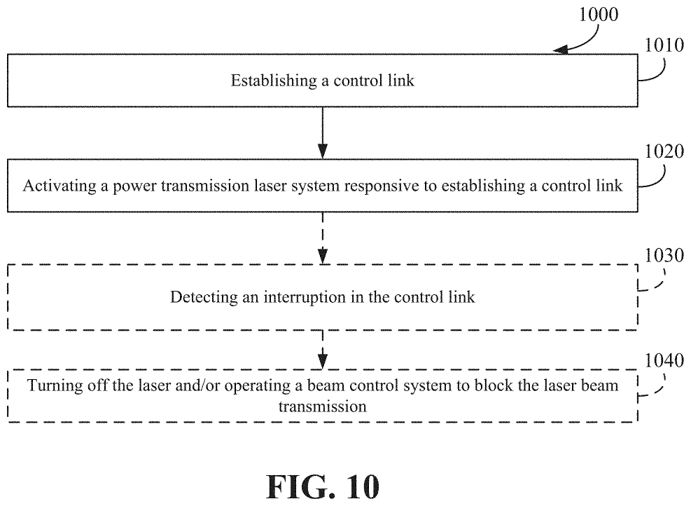

FIG. 10 depicts an example process 1000 for transmitting power to an airship. The process 1000 includes activating a control link (block 1010). Activating the control link can include activating a control link laser system to generate a control link laser beam. In other implementations, activating a control link can include establishing a communication link with a communications system of the airship. In still other implementations, activating the control link can include transmitting an IR or RF signal to an IR or RF receiver or transceiver of the airship.

In some implementations, data responsive to the control link can be communicated to a power transmission system, such as via a retroreflected control link laser beam and/or through the communication link. Such data can include a size, spatial profile, and/or other data indicative of an energy collection system of the airship.

The process 1000 includes activating a power transmission laser system responsive to establishing a control link (block 1020). The power transmission laser system can be configured in accordance with the system 800 described in reference to FIG. 8. Activating the power transmission laser system can include adjusting the intensity of power transmission and/or the orientation of the laser, either directly or through a beam control system, to achieve a desired irradiance level and/or a spatial profile at an energy collection system of an airship. Once the power transmission laser system is activated, power is transmitted to the energy collection system of the airship.

In some implementations, if the airship drifts or one or more control links become misaligned, the power transmission system can be configured to adjust a power and/or direction of an output laser beam of the power transmission system, either directly or through a beam control system.

In some implementations, the process 1000 can include detecting an interruption in the control link (block 1030). An interruption in the control link can include an object, such as an aircraft, an animal, a person, or any other object, entering between or otherwise disrupting the control link laser beam and a control link component. In other instances, the interruption in the control link can include the airship moving or otherwise becoming misaligned.

Responsive to the interruption, the process 1000 can include turning off or pausing the laser and/or operating a beam control system to block the laser beam transmission (block 1040).

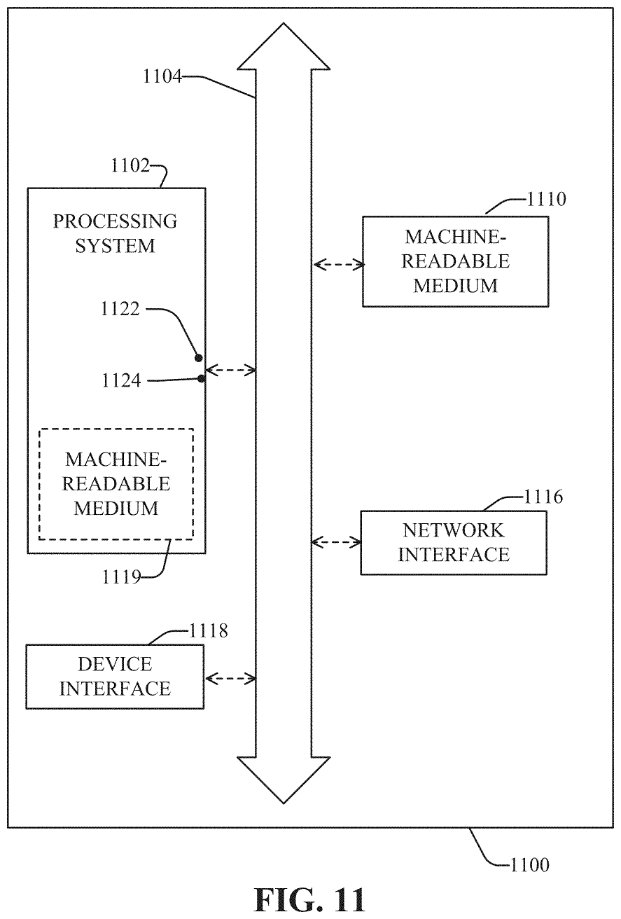

FIG. 11 is a diagram illustrating an example of a system 1100 for implementing some aspects such as the controller. The system 1100 includes a processing system 1102, which may include one or more processors or one or more processing systems. A processor may be one or more processors. The processing system 1102 may include a general-purpose processor or a specific-purpose processor for executing instructions and may further include a machine-readable medium 1119, such as a volatile or non-volatile memory, for storing data and/or instructions for software programs. The instructions, which may be stored in a machine-readable medium 1110 and/or 1119, may be executed by the processing system 1102 to control and manage access to the various networks, as well as provide other communication and processing functions. The instructions may also include instructions executed by the processing system 1102 for various user interface devices, such as a display and a keypad. The processing system 1102 may include an input port 1122 and an output port 1124. Each of the input port 1122 and the output port 1124 may include one or more ports. The input port 1122 and the output port 1124 may be the same port (e.g., a bi-directional port) or may be different ports.

The processing system 1102 may be implemented using software, hardware, or a combination of both. By way of example, the processing system 1102 may be implemented with one or more processors. A processor may be a general-purpose microprocessor, a microcontroller, a Digital Signal Processor (DSP), an Application Specific Integrated Circuit (ASIC), a Field Programmable Gate Array (FPGA), a Programmable Logic Device (PLD), a controller, a state machine, gated logic, discrete hardware components, or any other suitable device that can perform calculations or other manipulations of information.

A machine-readable medium may be one or more machine-readable media, including no-transitory or tangible machine-readable media. Software shall be construed broadly to mean instructions, data, or any combination thereof, whether referred to as software, firmware, middleware, microcode, hardware description language, or otherwise. Instructions may include code (e.g., in source code format, binary code format, executable code format, or any other suitable format of code).

Machine-readable media (e.g., 1119) may include storage integrated into a processing system such as might be the case with an ASIC. Machine-readable media (e.g., 1110) may also include storage external to a processing system, such as a Random Access Memory (RAM), a flash memory, a Read Only Memory (ROM), a Programmable Read-Only Memory (PROM), an Erasable PROM (EPROM), registers, a hard disk, a removable disk, a CD-ROM, a DVD, or any other suitable storage device. Those skilled in the art will recognize how best to implement the described functionality for the processing system 1102. According to one aspect of the disclosure, a machine-readable medium may be a computer-readable medium encoded or stored with instructions and may be a computing element, which provides structural and functional interrelationships between the instructions and the rest of the system, which permit the instructions' functionality to be realized. Instructions may be executable, for example, by the processing system 1102 or one or more processors. Instructions can be, for example, a computer program including code for performing methods of some of the embodiments.

A network interface 1116 may be any type of interface to a network (e.g., an Internet network interface), and may reside between any of the components shown in FIG. 11 and coupled to the processor via the bus 1104.

A device interface 1118 may be any type of interface to a device and may reside between any of the components shown in FIG. 11. A device interface 1118 may, for example, be an interface to an external device (e.g., a universal serial bus (USB) device) that plugs into a port (e.g., USB port) of the system 1100.

The foregoing description is provided to enable a person skilled in the art to practice the various configurations described herein. While the subject technology has been particularly described with reference to the various figures and configurations, it should be understood that these are for illustration purposes only and should not be taken as limiting the scope of the subject technology. In some aspects, the subject technology may be used in various markets, including for example and without limitation, advanced sensors and mobile space platforms.

There may be many other ways to implement the subject technology. Various functions and elements described herein may be partitioned differently from those shown without departing from the scope of the subject technology. Various modifications to these embodiments may be readily apparent to those skilled in the art, and generic principles provided herein may be applied to other embodiments. Thus, many changes and modifications may be made to the subject technology, by one having ordinary skill in the art, without departing from the scope of the subject technology.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases. Every combination of components described or exemplified can be used to practice the embodiments, unless otherwise stated. Some embodiments can be modified to incorporate any number of variations, alterations, substitutions or equivalent arrangements not heretofore described, but which are commensurate with the spirit and scope of the embodiments. Additionally, while various embodiments of the disclosure have been described, it is to be understood that aspects of the disclosure may include only some of the described embodiments. Accordingly, the disclosure is not to be seen as limited by the foregoing description.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. All structural and functional equivalents to the elements of the various embodiments described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

What is claimed is:

1. A system comprising:
an airship comprising:
an outer casing having an exterior surface and containing a gas therein;
an energy storage system comprising one or more energy storage devices;
an energy distribution and control system electrically coupled to the energy storage system and configured to distribute power from the energy storage system to one or more systems of the airship; and
an energy collection system coupled to the exterior surface of the outer casing, the energy collection system comprising:
a laser tolerant layer,
an insulation layer,
a plurality of photovoltaic cells arranged in an array and electrically coupled to the energy storage system, and
one or more retroreflectors positioned adjacent the array of photovoltaic cells; and
a power transmission system comprising:
a plurality of power transmission lasers;
a beam control system for the plurality of power transmission lasers;
one or more control link lasers; and
a controller configured to:
establish a control link between the power transmission system and the airship via the one or more control link lasers and the retroreflectors of the airship, and
control the plurality of power transmission lasers to transmit power to the airship;
wherein the laser beams of the plurality of power transmission lasers overlap to achieve a substantially uniform irradiance level and power distribution spatial profile at the plurality of photovoltaic cells of the airship.

2. An airship comprising:
an outer casing;
an energy storage system comprising one or more energy storage devices;
an energy distribution and control system electrically coupled to the energy storage system and configured to distribute power from the energy storage system to one or more systems of the airship; and
an energy collection system positioned outside the outer casing, the energy collection system comprising:
a plurality of photovoltaic cells arranged in an array and electrically coupled to the energy storage system, and
one or more control link components positioned adjacent the array of photovoltaic cells;
wherein the one or more control link components are configured to establish a control link between the airship and a power transmission system; and
wherein the plurality of photovoltaic cells are configured to transfer laser beam transmitted energy from the power transmission system to the energy storage system.

3. The airship of claim 2, wherein the one or more control link components are retroreflectors.

4. The airship of claim 2, wherein the one or more control link components are infrared receivers.

5. The airship of claim 2, wherein the energy collection system further comprises an insulation layer.

6. The airship of claim 2, wherein the energy collection system further comprises a laser tolerant layer.

7. The airship of claim 2, wherein the energy collection system is offset from the outer casing.

8. The airship of claim 2, wherein the plurality of photovoltaic cells are infrared photovoltaic cells.

9. The airship of claim 2, wherein the outer casing is reinforced at a location of the energy collection system.

10. A power transmission system comprising:
a plurality of power transmission lasers;
a beam control system for the plurality of power transmission lasers;
one or more control link lasers; and
a controller configured to:
establish a control link between the power transmission system and an airship via the one or more control link lasers and one or more control link components of the airship, and
control the plurality of power transmission lasers to transmit power to the airship;
wherein the laser beams of the plurality of power transmission lasers overlap to achieve a substantially uniform irradiance level and power distribution spatial profile at a plurality of photovoltaic cells of the airship.

11. The power transmission system of claim 10, wherein the plurality of power transmission lasers are solid state lasers.

12. The power transmission system of claim 10, wherein the plurality of power transmission lasers are fiber lasers.

13. The power transmission system of claim 12, wherein the fiber lasers have a wavelength of between 1020 nm and 1100 nm, the wavelength being selected by the controller based at least in part on a spectral response of the plurality of photovoltaic cells of the airship.

14. The power transmission system of claim 10, wherein the plurality of power transmission lasers are laser diodes.

15. The power transmission system of claim 10, wherein the plurality of power transmission lasers are IR lasers.

16. The power transmission system of claim 10, wherein the plurality of power transmission lasers have a wavelength of between 400 nm and 1200 nm.

17. The power transmission system of claim 10, wherein the plurality of power transmission lasers have a wavelength of 1060 nm.

18. The power transmission system of claim 10, wherein the power transmission system is an air-based remote power transmission system.

19. The power transmission system of claim 10, wherein the power transmission system is a ground-based remote power transmission system.

20. The power transmission system of claim 10, wherein the power transmission system is a sea-based remote power transmission system.

21. The power transmission system of claim 10, wherein the controller is further configured to pause or turn off the plurality of power transmission lasers responsive to an interruption of the control link.

22. An energy collection system comprising:
a plurality of photovoltaic cells arranged in an array and electrically coupled to an energy storage system; and
one or more control link components positioned adjacent the array of photovoltaic cells;
wherein the one or more control link components are configured to establish a control link with a power transmission system; and
wherein the plurality of photovoltaic cells are configured to transfer laser beam transmitted energy from the power transmission system to the energy storage system.

23. An energy collection system comprising:
a plurality of thermo-electrical cells arranged in an array and electrically coupled to an energy storage system; and
one or more control link components positioned adjacent the array of thermo-electrical cells;
wherein the one or more control link components are configured to establish a control link with a power transmission system; and
wherein the plurality of thermo-electrical cells are configured to transfer laser beam transmitted energy from the power transmission system to the energy storage system.

24. An energy collection system comprising:
a plurality of pyroelectrical cells arranged in an array and electrically coupled to an energy storage system; and
one or more control link components positioned adjacent the array of pyroelectrical cells;
wherein the one or more control link components are configured to establish a control link with a power transmission system; and
wherein the plurality of pyroelectrical cells are configured to transfer laser beam transmitted energy from the power transmission system to the energy storage system.

25. An energy collection system comprising:
means for establishing a control link with a power transmission system; and
means for converting and transferring laser beam transmitted energy from the power transmission system to an energy storage system.

26. A power transmission system comprising:
means for establishing a control link with an energy collection system of an airship; and
means for transmitting power to the airship responsive to establishing the control link.

27. An energy collection system comprising:
a plurality of photothermal cells arranged in an array and electrically coupled to an energy storage system; and
one or more control link components positioned adjacent the array of photothermal cells;
wherein the one or more control link components are configured to establish a control link with a power transmission system; and
wherein the plurality of photothermal cells are configured to transfer laser beam transmitted energy from the power transmission system to the energy storage system.

28. An energy collection system comprising:
a plurality of optical rectennas arranged in an array and electrically coupled to an energy storage system; and
one or more control link components positioned adjacent the array of optical rectennas;
wherein the one or more control link components are configured to establish a control link with a power transmission system; and
wherein the plurality of optical rectennas are configured to transfer laser beam transmitted energy from the power transmission system to the energy storage system.
